(19) United States
(12) Patent Application Publication
(10) Pub. No.: US 2019/0097124 A1
(43) Pub. Date: Mar. 28, 2019

(54) MAGNETORESISTIVE RANDOM ACCESS MEMORY DEVICE

(71) Applicant: Samsung Electronics Co., Ltd., Suwon-si (KR)

(72) Inventors: Joon-Myoung LEE, Anyang-si (KR); Ju-Hyun KIM, Yongin-si (KR); Jung-Hwan PARK, Seoul (KR); Se-Chung OH, Yongin-si (KR); Young-Man JANG, Hwaseong-si (KR)

(21) Appl. No.: 16/101,243

(22) Filed: Aug. 10, 2018

(30) Foreign Application Priority Data
Sep. 27, 2017 (KR) 10-2017-0125477

(51) Int. Cl. H01L 43/02; H01L 43/10; H01L 43/12; H01L 27/22

(52) U.S. Cl. CPC H01L 43/02; H01L 27/222; H01L 43/12; H01L 43/10

(57) ABSTRACT

An MRAM device includes a lower electrode, a blocking pattern on the lower electrode and including a binary metal boride in an amorphous state, a seed pattern on the blocking pattern and including a metal, an MTJ structure on the seed pattern, and an upper electrode on the MTJ structure.

### CROSS-REFERENCE TO RELATED APPLICATION

This application claims priority under 35 U.S.C. § 119 to Korean Patent Application No. 10-2017-0125477, filed on Sep. 27, 2017 in the Korean Intellectual Property Office (KIPO), the disclosure of which is incorporated by reference in its entirety.

### BACKGROUND

### 1. Technical Field

The present inventive concept relates to a magnetoresistive random access memory (MRAM) device.

### 2. Description of Related Art

A magnetic tunnel junction (MTJ) structure may be embedded in a logic device. In fabrication of the logic device, the MTJ structure may be subject to high temperature processes for forming wirings after the MTJ structure is formed in the logic device. The characteristics of the MTJ structure may be influenced by the crystallinity of the lower electrode.

### SUMMARY

Example embodiments provide an MRAM device having good characteristics.

According to example embodiments, there is provided an MRAM device. The MRAM device may include a lower electrode, a blocking pattern on the lower electrode and including a binary metal boride in an amorphous state, a seed pattern on the blocking pattern and including a metal, an MTJ structure on the seed pattern, and an upper electrode on the MTJ structure.

According to example embodiments, there is provided an MRAM device. The MRAM device may include a lower electrode, a blocking pattern on the lower electrode and including a first metal boride that is formed by combining a first metal and boron, a seed pattern on the blocking pattern and including a second metal, an MTJ structure on the seed pattern, and an upper electrode on the MTJ structure. A formation energy of the first metal boride may be less than a formation energy of a second metal boride that is formed by combining a second metal and boron.

According to example embodiments, there is provided an MRAM device. The MRAM device may include a lower electrode, a blocking pattern on the lower electrode and including a ternary metal boron nitride in an amorphous state, a seed pattern on the blocking pattern and including a metal, an MTJ structure on the seed pattern, and an upper electrode on the MTJ structure.

According to example embodiments, there is provided an MRAM device. The MRAM device may include an active fin on a substrate, a gate structure on the active fin, first and second source/drain layers on portions of the active fin adjacent to the gate structure, a source line electrically connected to the first source/drain layer, a lower electrode electrically connected to the second source/drain layer, a blocking pattern on the lower electrode, the blocking pattern including a binary metal boride in an amorphous state, a seed pattern on the blocking pattern, the seed pattern including a metal, an MTJ structure on the seed pattern, an upper electrode on the MTJ structure, and a bit line electrically connected to the upper electrode.

The MRAM device in accordance with example embodiments may include the blocking pattern between the lower electrode and the seed pattern, and thus the desired characteristics of the fixed layer pattern on the seed pattern, e.g., a magnetization direction thereof may be kept during a high temperature process.

### BRIEF DESCRIPTION OF THE DRAWINGS

These and other features of the present inventive concept will become more apparent by describing in detail exemplary embodiments thereof with reference to the accompanying drawings of which:

FIG. 1 is a cross-sectional view illustrating an MRAM device in accordance with example embodiments;

FIG. 2 is a cross-sectional view illustrating a method of manufacturing an MRAM device in accordance with example embodiments;

FIG. 3 is a cross-sectional view illustrating an MRAM device in accordance with example embodiments;

FIGS. 4 and 5 are cross-sectional views illustrating an MRAM device in accordance with example embodiments; and

FIGS. 6 to 27 are plan views and cross-sectional views illustrating a method of manufacturing an MRAM device in accordance with example embodiments.

### DETAILED DESCRIPTIONS OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. Like reference numerals may refer to the like elements throughout the specification and drawings.

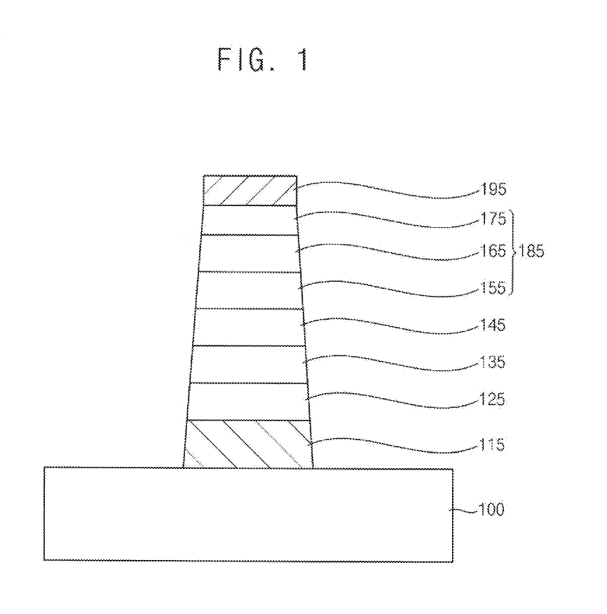

FIG. 1 is a cross-sectional view illustrating an MRAM device in accordance with example embodiments.

Referring to FIG. 1, the MRAM device may include a lower electrode 115, a first blocking pattern 125, an adhesion pattern 135, a seed pattern 145, an MTJ structure 185, and an upper electrode 195 sequentially stacked on a substrate 100. The MTJ structure 185 may include a fixed layer pattern 155, a tunnel barrier layer pattern 165, and a free layer pattern 175 sequentially stacked.

The substrate 100 may include a semiconductor material, e.g., silicon, germanium, silicon-germanium, or III-V semiconductor compounds, e.g., GaP, GaAs, GaSb, etc. In an example embodiment, the substrate 100 may be a silicon-on-insulator (SOI) substrate or a germanium-on-insulator (GOI) substrate.

Various constituent elements of the MRAM device, e.g., word lines, transistors, diodes, source/drain layers, contact plugs, vias, wirings, etc., and an insulating interlayer covering the constituent elements may be formed on the substrate 100.

The lower electrode 115 may include a metal nitride, e.g., titanium nitride, tantalum nitride, tungsten nitride, etc.

The first blocking pattern 125 may block the influence of the crystallinity of the lower electrode 115 on the seed pattern 145. In example embodiments, the first blocking pattern 125 may include a binary metal compound in an amorphous state, and stay amorphous, for example, at a high temperature equal to or more than about 400° C. Additionally, the first blocking pattern 125 may include a material having a good roughness on the lower electrode 115, e.g., boron.

Thus, the first blocking pattern 125 may include a binary metal boride, e.g., tantalum boride, titanium boride, hafnium boride, zirconium boride, vanadium boride, niobium boride, scandium boride, etc. For example, the first blocking pattern 125 may include one of tantalum boride, titanium boride, hafnium boride, zirconium boride, vanadium boride, niobium boride, and scandium boride.

In example embodiments, the first blocking pattern 125 may include tantalum boride, which may include boron in an amount in a range of about 5 wt % to about 40 wt %.

Alternatively, the first blocking pattern 125 may include a ternary metal boron nitride. For example, the first blocking pattern 125 may include tantalum boron nitride, titanium boron nitride, hafnium boron nitride, zirconium boron nitride, vanadium boron nitride, niobium boron nitride, scandium boron nitride, etc. In example embodiments, the first blocking pattern 125 may include one of tantalum boron nitride, titanium boron nitride, hafnium boron nitride, zirconium boron nitride, vanadium boron nitride, niobium boron nitride, and scandium boron nitride.

In example embodiments, the first blocking pattern 125 may include tantalum boron nitride, which may include boron in an amount in a range of about 2.5 wt % to about 20 wt % and nitrogen in an amount in a range of about 2.5 wt % to about 20 wt %.

The adhesion pattern 135 may enhance the adhesion between the first blocking pattern 125 and the seed pattern 145. In example embodiments, the adhesion pattern 135 may include tantalum, titanium, etc.

The seed pattern 145 may serve to facilitate the fixed layer pattern 155 of the MTJ structure 185 to grow in a desired crystal direction. The seed pattern 145 may include a metal, e.g., ruthenium, rhenium, iridium, rhodium, hafnium, etc. In example embodiments, the seed pattern 145 may include only one type of metal. For example, the seed pattern 145 may include one of ruthenium, rhenium, iridium, rhodium, and hafnium. In example embodiments, the seed pattern 145 may include ruthenium.

The fixed layer pattern 155 may include a ferromagnetic material, e.g., cobalt, platinum, iron, nickel, etc. In an example embodiment, the fixed layer pattern 155 may include an alloy of cobalt and platinum, i.e., CoPt, or a multi-layered structure including a cobalt layer and a platinum layer alternately stacked.

The tunnel barrier layer pattern 165 may include, e.g., magnesium oxide or aluminum oxide, and the free layer pattern 175 may include a ferromagnetic material, e.g., cobalt, platinum, iron, nickel, etc.

In example embodiments, in the MTJ structure 185, the location of the fixed layer pattern 155 and the free layer pattern 175 may be changed, or at least one of the fixed layer pattern 155, the tunnel barrier layer pattern 165, and the free layer pattern 175 may be formed at a plurality of levels.

Each of the fixed layer pattern 155 and the free layer pattern 175 in the MTJ structure 185 may have a vertical or horizontal magnetization direction. The magnetization direction of the fixed layer pattern 155 may be fixed. The magnetization direction of the free layer pattern 175 may be switched by 180 degrees, which is caused by a switching current applied to the MTJ structure 185.

The upper electrode 195 may include a metal, e.g., titanium, tantalum, tungsten, etc., or a metal nitride, e.g., titanium nitride, tantalum nitride, tungsten nitride, etc.

As illustrated above, the first blocking pattern 125 may include a first metal that is combined with boron with a first boride formation energy. That is, the first metal may be combined with boron with the first boride formation energy to form the metal boride of the first blocking pattern 25. As illustrated above, the seed pattern 145 may include a second metal that is combined with boron with a second boride formation energy to form a metal boride. In example embodiments, the first boride formation energy may be less than the second boride formation energy.

When the seed pattern 145 includes ruthenium, the second boride formation energy may be about 0.0 eV, and the first boride formation energy of the first metal of the first blocking pattern 125 may have a value less than 0.0 eV, i.e., a negative value. For example, when the first blocking pattern 125 includes tantalum, the first boride formation energy may be about −0.7 eV.

As the first boride formation energy of the first metal of the first blocking pattern 125 is less than the second boride formation energy of the second metal of the seed pattern 145, boron of the first blocking pattern 125 including a metal boride may be prevented from diffusing into the seed pattern 145. As illustrated above, as the first blocking pattern 125 may stay amorphous at a high temperature equal to or more than about 400° C., the first blocking pattern 125 may stay amorphous even in a high temperature process for forming wirings.

Accordingly, the first blocking pattern 125 may not change the characteristics of the seed pattern 145 due to the boron diffusion, and effectively block the influence of the crystallinity of the lower electrode 115 on the crystallinity of the seed pattern 145. As a result, as the MRAM device includes the first blocking pattern 125, the fixed layer pattern 155 on the seed pattern 145 may keep its desired characteristics, e.g., magnetization direction.

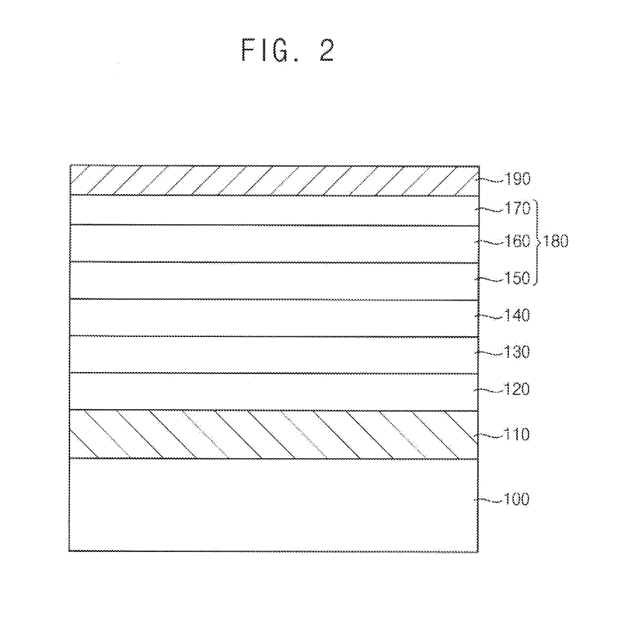

FIG. 2 is a cross-sectional view illustrating a method of manufacturing an MRAM device in accordance with example embodiments.

Referring to FIG. 2, a lower electrode layer 110, a first blocking layer 120, an adhesion layer 130, a seed layer 140, an MTJ structure layer 180, and an upper electrode layer 190 may be sequentially formed on a substrate 100. The MTJ structure layer 180 may include a fixed layer 150, a tunnel barrier layer 160, and a free layer 170 sequentially stacked.

Various constituent elements of the MRAM device, e.g., word lines, transistors, diodes, source/drain layers, contact plugs, vias, wirings, etc., and an insulating interlayer covering the elements may be formed on the substrate 100.

The lower electrode layer 110 may include a metal nitride, e.g., titanium nitride, tantalum nitride, tungsten nitride, etc.

In example embodiments, the first blocking layer 120 may include a binary metal compound in an amorphous state, and stay amorphous, for example, at a high temperature equal to or more than about 400° C. The metal compound may include a material such as boron, thereby having a good roughness on the lower electrode layer 110.

Thus, the first blocking layer 120 may include a metal boride, e.g., tantalum boride, titanium boride, hafnium boride, zirconium boride, vanadium boride, niobium boride, scandium boride, etc.

In example embodiments, the first blocking layer 120 may include tantalum boride, which may include boron in an amount in a range of about 5 wt % to about 40 wt %.

Alternatively, the first blocking layer 120 may include a metal boron nitride. For example, the first blocking layer 120 may include tantalum boron nitride, titanium boron nitride, hafnium boron nitride, zirconium boron nitride, vanadium boron nitride, niobium boron nitride, scandium boron nitride, etc.

In example embodiments, the first blocking layer 120 may include tantalum boron nitride, which may include boron in an amount in a range of about 2.5 wt % to about 20 wt % and nitrogen in an amount in a range of about 2.5 wt % to about 20 wt %.

The first blocking layer 120 may be formed by, e.g., a sputtering process, a physical vapor deposition (PVD) process, a chemical vapor deposition (CVD) process, etc.

In example embodiments, the adhesion layer 130 may include tantalum, titanium, etc.

The seed layer 140 may include a metal, e.g., ruthenium, rhenium, iridium, rhodium, hafnium, etc. In example embodiments, the seed layer 140 may include ruthenium.

The fixed layer 150 may include a ferromagnetic material, e.g., cobalt, platinum, iron, nickel, etc. In an example embodiment, the fixed layer 150 may include an alloy of cobalt and platinum, i.e., CoPt, or a multi-layered structure including a cobalt layer and a platinum layer alternately stacked.

The tunnel barrier layer 160 may include, e.g., magnesium oxide or aluminum oxide, and the free layer 170 may include a ferromagnetic material, e.g., cobalt, platinum, iron, nickel, etc.

The MTJ structure layer 180 may include a free layer 170, a tunnel barrier layer 160, and a fixed layer 150 sequentially stacked. At least one of the fixed layer 150, the tunnel barrier layer 160, and the free layer 170 may be formed at a plurality of levels.

Each of the adhesion layer 130, the seed layer 140, and the MTJ structure layer 180 may be formed by, e.g., a sputtering process, a PVD process, a CVD process, etc.

The upper electrode layer 190 may include a metal, e.g., titanium, tantalum, tungsten, etc., or a metal nitride, e.g., titanium nitride, tantalum nitride, tungsten nitride, etc.

A first metal of the first blocking layer 120 may have a first boride formation energy, and a second metal of the seed layer 140 may have a second boride formation energy greater than the first boride formation energy. Thus, boron of the first blocking layer 120 may be prevented from diffusing into the seed layer 140. As illustrated above, as the first blocking layer 120 may stay amorphous at a high temperature equal to or more than about 400° C., the first blocking layer 120 may stay amorphous even in a high temperature process for forming wirings.

Accordingly, the first blocking layer 120 may not change the characteristics of the seed layer 140 due to the boron diffusion, and effectively block the influence of the crystallinity of the lower electrode layer 110 on the crystallinity of the seed layer 140. As a result, the fixed layer 150 on the seed layer 140 may keep its desired characteristics, e.g., magnetization direction.

Referring to FIG. 1 back, a photoresist pattern (not shown) may be formed on the upper electrode layer 190, and the upper electrode layer 190 may be etched using the photoresist pattern as an etching mask to form the upper electrode 195.

The MTJ structure layer 180, the seed layer 140, the adhesion layer 130, the first blocking layer 120, the lower electrode layer 110 may be sequentially etched using the upper electrode 195 as an etching mask to form the lower electrode 115, the first blocking pattern 125, the adhesion pattern 135, the seed pattern 145, and the MTJ structure 185 sequentially stacked on the substrate 100. The MTJ structure 185 may include the fixed layer pattern 155, the tunnel barrier layer pattern 165, and the free layer pattern 175 sequentially stacked.

In example embodiments, the etching process may be performed by a physical etching process, e.g., an ion beam etching (IBE) process using ions of, e.g., argon, krypton, etc.

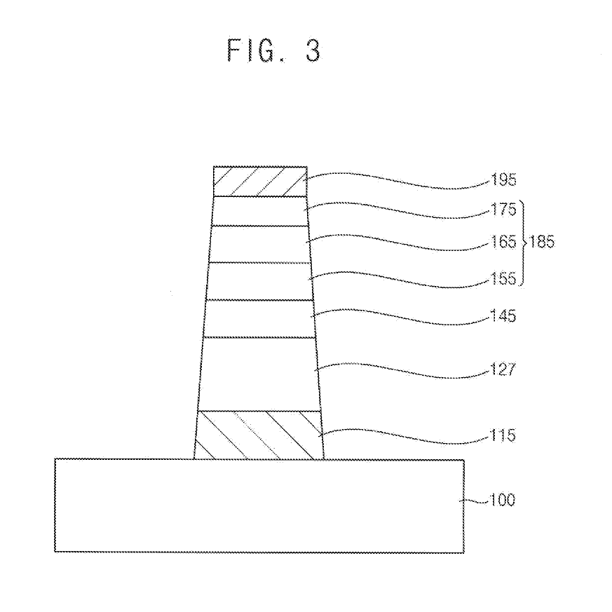

FIG. 3 is a cross-sectional view illustrating an MRAM device in accordance with example embodiments. The MRAM device may be substantially the same as or similar to that of FIG. 1, except for the first blocking pattern 125 and the adhesion pattern 135.

Referring to FIG. 3, the MRAM device may include the lower electrode 115, a second blocking pattern 127, the seed pattern 145, the MTJ structure 185, and the upper electrode 195 sequentially stacked on the substrate 100. The MTJ structure 185 may include the fixed layer pattern 155, the tunnel barrier layer pattern 165, and the free layer pattern 175 sequentially stacked.

The MRAM device of FIG. 3 may include the second blocking pattern 127 instead of the first blocking pattern 125 without the adhesion pattern 135, unlike the MRAM device of FIG. 1. Thus, the second blocking pattern 127 may block the influence of the crystallinity of the lower electrode 115 on the crystallinity of the seed pattern 145, and further, may enhance the adhesion between the lower electrode 115 and the seed pattern 145.

In example embodiments, the second blocking pattern 127 may include a metal boride or a metal boron nitride of the first blocking pattern 125, which may include a metal of the adhesion pattern 135, e.g., tantalum boride, titanium boride, tantalum boron nitride, titanium boron nitride, etc.

The first boride formation energy of the first metal of the second blocking pattern 127 may be less than the second boride formation energy of the second metal of the seed pattern 145, and thus boron of the second blocking pattern 127 including a metal boride may be prevented from diffusing into the seed pattern 145. As the second blocking pattern 127 may stay amorphous at a high temperature equal to or more than about 400° C., the second blocking pattern 127 may stay amorphous in a high temperature process for forming wirings. Accordingly, the second blocking pattern 127 may not change the characteristics of the seed pattern 145 due to the boron diffusion, and effectively block the influence of the crystallinity of the lower electrode 115 on the crystallinity of the seed pattern 145. As a result, as the MRAM device includes the second blocking pattern 127, the fixed layer pattern 155 on the seed pattern 145 may keep its desired characteristics, e.g., a magnetization direction.

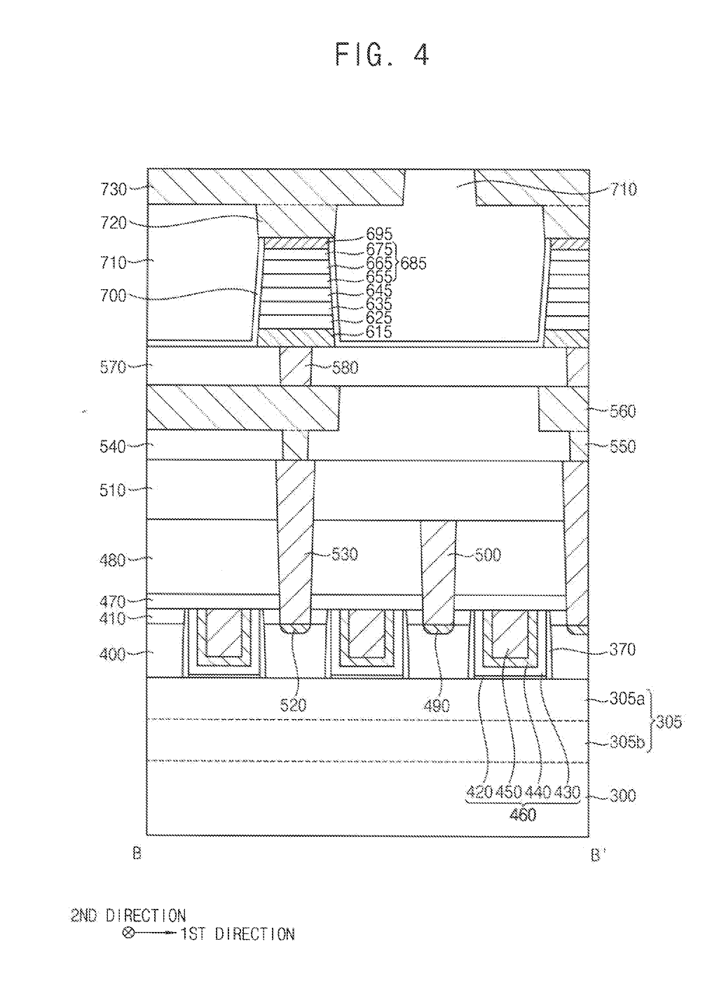

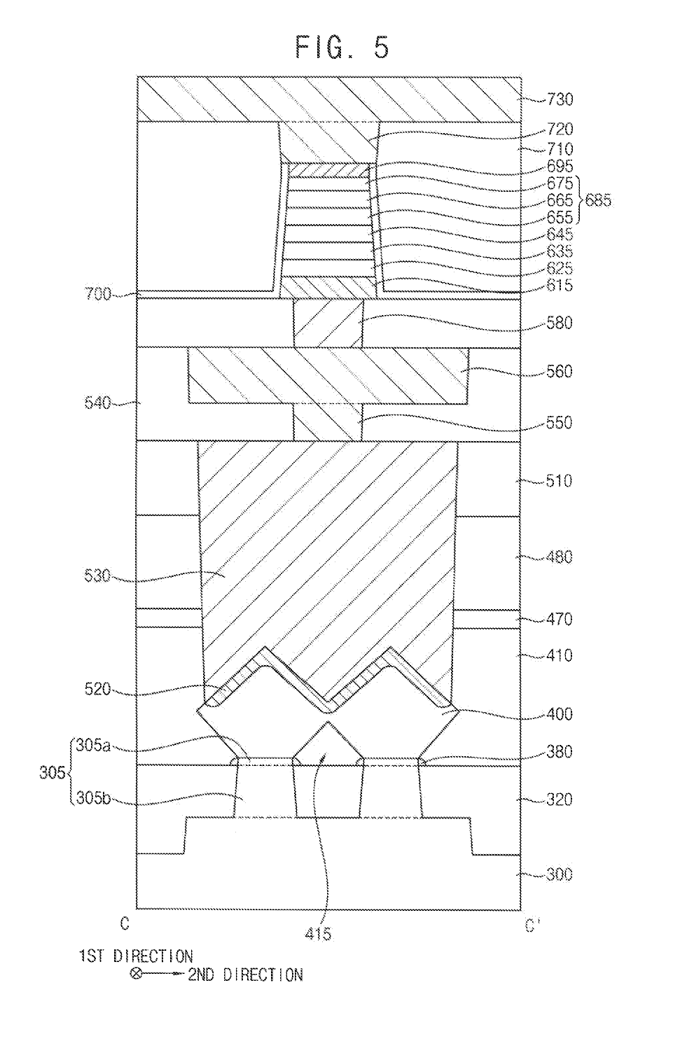

FIGS. 4 and 5 are cross-sectional views illustrating an MRAM device in accordance with example embodiments. FIG. 4 is a cross-sectional view taken along an extension direction of an active fin, and FIG. 5 is a cross-sectional view taken along an extension direction of a gate structure (refer to FIG. 18).

This MRAM device may include structures substantially the same as or similar to those of the MRAM device of FIG. 1, and thus detailed descriptions thereof will be omitted herein. In some embodiments, the MRAM device may include structures substantially the same as or similar to those of the MRAM device of FIG. 3.

Referring to FIGS. 4 and 5, the MRAM device may include an active fin 305 on a substrate 300, a gate structure 460 on the active fin 305, source/drain layers 400 on portions of the active fin 305 adjacent the gate structure 460, a source line 500 electrically connected to a first source/drain layer of the source/drain layers 400, a lower electrode 615 electrically connected to a second source/drain layer of the source/drain layers 400, and a first blocking pattern 625, an adhesion pattern 635, a seed pattern 645, an MTJ structure 685, and an upper electrode 695 sequentially stacked on the lower electrode 615.

The gate structure 460 may include an interface pattern 420, a gate insulation pattern 430, a work function control pattern 440, and a gate electrode 450 sequentially stacked, and the MTJ structure 685 may include a fixed layer pattern 655, a tunnel barrier layer pattern 665, and a free layer pattern 675 sequentially stacked.

The MRAM device may further include a gate spacer 370, a fin spacer 380, lower and upper contact plugs 530 and 580, first and second vias 550 and 720, first and second conductive lines 560 and 730, an isolation pattern 320, an insulation layer 410, a capping layer 470, first to fifth insulating interlayers 480, 510, 540, 570 and 710, and a protection layer 700.

The active fin 305 may extend in a first direction on the substrate 300. The active fin 305 may be in plural. The active fin 305 in plural may be formed in a second direction crossing the first direction. For example, the active fin 305 in plural may be spaced apart from each other in the second direction. The active fin 305 may include a material substantially the same as that of the substrate 300. The isolation pattern 320 may be formed on the substrate 300, and may include an oxide, e.g., silicon oxide. The active fin 305 may include a lower active pattern 305b of which a sidewall may be surrounded by the isolation pattern 320, and an upper active pattern 305a protruding from an upper surface of the isolation pattern 320.

The gate structure 460 may extend in the second direction on the active fin 305 and the isolation pattern 320. The gate structure 460 may be in plural. The gate structure 460 in plural may be formed in the first direction. For example, the gate structure 460 in plural may be spaced apart from each other in the first direction. The gate structure 460 together with the source/drain layer 400 may form a transistor, which may include a P-type Metal-Oxide-Semiconductor (PMOS) transistor or an N-type Metal-Oxide-Semiconductor (NMOS) transistor according to the conductivity type of the source/drain layer 400.

The interface pattern 420 may be formed on an upper surface of the active fin 305, and may include an oxide, e.g., silicon oxide. The gate insulation pattern 430 may be formed on the interface pattern 420, the isolation pattern 320, and an inner sidewall of the gate spacer 370, and may include a metal oxide having a high-k dielectric constant, e.g., hafnium oxide, tantalum oxide, zirconium oxide, etc. The work function control pattern 440 may be formed on the gate insulation pattern 430 to surround a bottom and a sidewall of the gate electrode 450, and may include a metal nitride or a metal alloy, e.g., titanium nitride, titanium aluminum, titanium aluminum nitride, tantalum nitride, tantalum aluminum nitride, etc. The gate electrode 450 may include a low-k resistance metal, e.g., aluminum, copper, tantalum, or a nitride thereof.

The gate spacer 370 may cover a sidewall of the gate structure 460, and the fin spacer 380 may be formed on a sidewall of the active fin 305. The gate spacer 370 and the fin spacer 380 may include a nitride, e.g., silicon nitride.

Each of the source/drain layers 400 may include single crystalline silicon-germanium doped with p-type impurities. Alternatively, each of the source/drain layers 400 may include single crystalline silicon carbide doped with n-type impurities or single crystalline silicon doped with n-type impurities. Each of the source/drain layers 400 may grow in each of vertical and horizontal directions by a selective epitaxial growth (SEG) process on an upper surface of the active fin 305. Each of the source/drain layers 400 may be in contact with a sidewall of the gate spacer 370. In example embodiments, when the distance between neighboring ones of the active fins 305 is small, the source/drain layers 400 growing from the neighboring ones of the active fins 305 may be merged with each other.

The insulation layer 410 may be formed on the source/drain layers 400 to surround an outer sidewall of the gate spacer 370 covering the sidewall of the gate structure 460. The capping layer 470 may be formed on the insulation layer 410, the gate structure 460 and the gate spacer 370. The insulation layer 410 may include an oxide, e.g., silicon oxide, the capping layer 470 may include a nitride, e.g., silicon nitride. An air gap 415 may be formed in a space between the merged source/drain layers 400 and the isolation pattern 320. The insulation layer 410 may not be present within the air gap 415.

The first to fifth insulating interlayers 480, 510, 540, 570 and 710 may be sequentially formed on the capping layer 470. The first to fifth insulating interlayers 480, 510, 540, 570 and 710 may include an oxide, e.g., silicon oxide, or a low-k dielectric material.

The source line 500 may be formed on the first source/drain layer of the source/drain layers 400. For example, the source line 500 may extend through the insulation layer 410, the capping layer 470, and the first insulating interlayer 480. A first metal silicide pattern 490 may be formed between the first source/drain layer and the source line 500. For example, the source line 500 may be in contact with the first metal silicide pattern 490. The source line 500 may include a first barrier pattern (not shown) and a first conductive pattern (not shown). The first metal silicide pattern 490 may include a metal silicide, e.g., cobalt silicide, nickel silicide, etc.

In example embodiments, the source line 500 may extend in the second direction to a given length. The source line 500 may be formed in plural. The source line 500 in plural may be formed in the first direction. For example, the source line 500 in plural may be spaced apart from each other in the first direction.

The lower contact plug 530 may be formed on the second source/drain layer of the source/drain layers 400. For example, the lower contact plug 530 may extend through the insulation layer 410, the capping layer 470, and the first and second insulating interlayers 480 and 510. A second metal silicide pattern 520 may be formed between the second source/drain layer and the lower contact plug 530. The lower contact plug 530 may include a second barrier pattern (not shown) and a second conductive pattern (not shown). In example embodiments, the lower contact plug 530 may be formed in plural. The lower contact plug 530 in plural may be formed in the first direction. For example, the lower contact plug 530 in plural may be spaced apart from each other in the first direction.

The first via 550 and the first conductive line 560 may extend through the third insulating interlayer 540. The first via 550 may be in contact with the lower contact plug 530. The first via 550 and the first conductive line 560 may include a third barrier pattern (not shown) and a third conductive pattern (not shown).

The upper contact plug 580 may extend through the fourth insulating interlayer 570. The upper contact plug 580 may be in contact with the first conductive line 560, and may include a fourth barrier pattern (not shown) and a fourth conductive pattern (not shown).

The lower electrode 615 may be formed on the fourth insulating interlayer 570 to be in contact with the upper contact plug 580. The first blocking pattern 625, the adhesion pattern 635, the seed pattern 645, the MTJ structure 685, and the upper electrode 695 sequentially stacked on the lower electrode 615 may be substantially the same as those of the MRAM device in FIG. 1.

The protection layer 700 may be formed on the fourth insulating interlayer 570 to cover sidewalls of the lower electrode 615, the first blocking pattern 625, the adhesion pattern 635, the seed pattern 645, the MTJ structure 685, and the upper electrode 695. The protection layer 700 may include a nitride, e.g., silicon nitride.

The fifth insulating interlayer 710 may be formed on the protection layer 700.

The second via 720 and the second conductive line 730 may extend through the fifth insulating interlayer 710 to be in contact with the upper electrode 695, and may include a fifth barrier pattern (not shown) and a fifth conductive pattern (not shown).

In example embodiments, the second conductive line 730, extending in the second direction, may serve as a bit line of the MRAM device.

As illustrated above, the MRAM device may include the first blocking pattern 625 between the lower electrode 615 and the seed pattern 645, and the first boride formation energy of the first metal of the first blocking pattern 625 may be less than the second boride formation energy of the second metal of the seed pattern 645. Thus, boron of the first blocking pattern 625 including a metal boride may be prevented from diffusing into the seed pattern 645.

As the first blocking pattern 625 may stay amorphous at a high temperature equal to or more than about 400° C., the first blocking pattern 625 may stay amorphous when a high temperature process for forming the second via 720 and the second conductive line 730 is performed. Accordingly, the influence of the crystallinity of the lower electrode 615 on the crystallinity of the seed pattern 645 may be effectively blocked by the first blocking pattern 625, and the fixed layer pattern 655 on the seed pattern 645 may have desired characteristics, e.g., a magnetization direction.

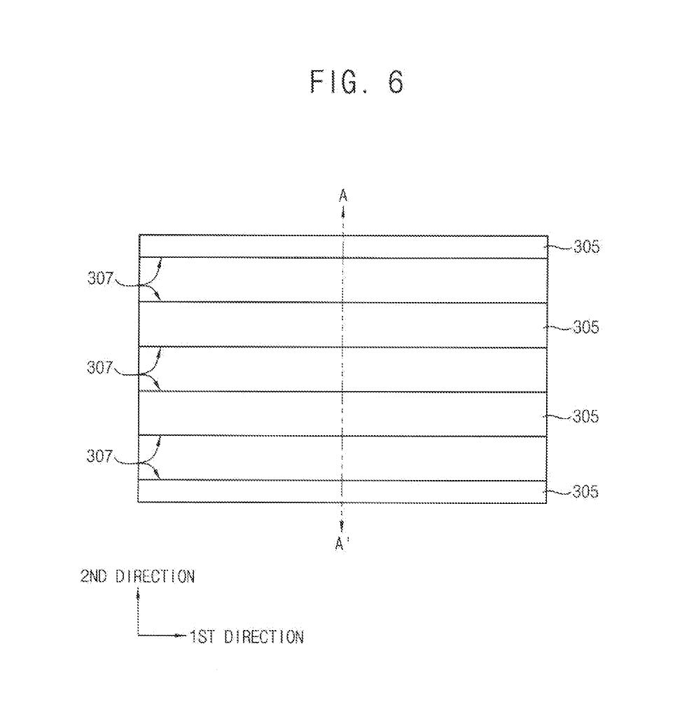

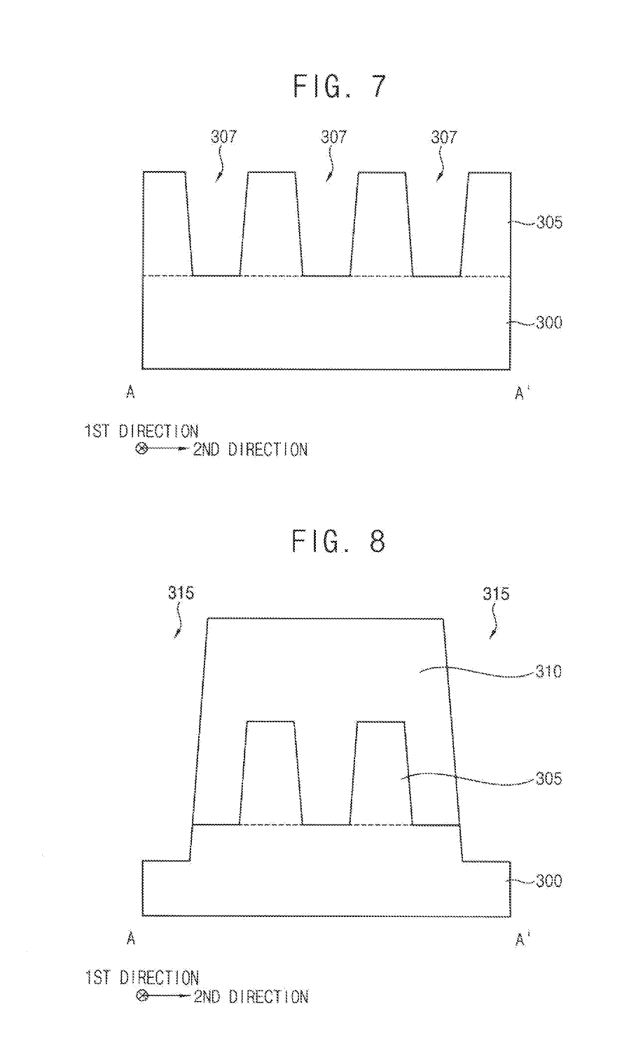

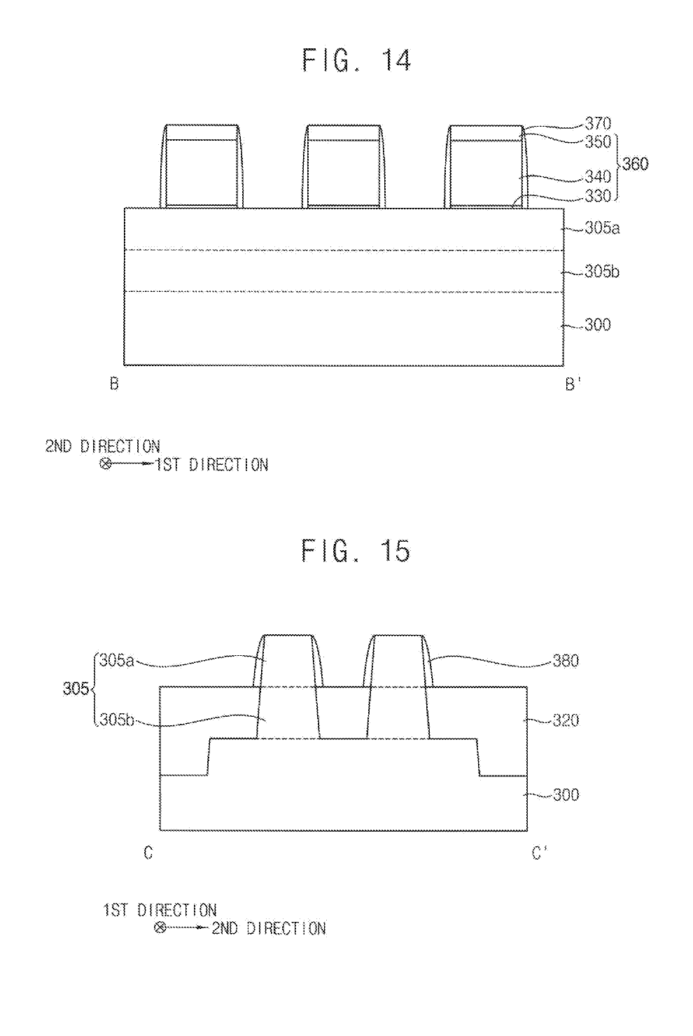

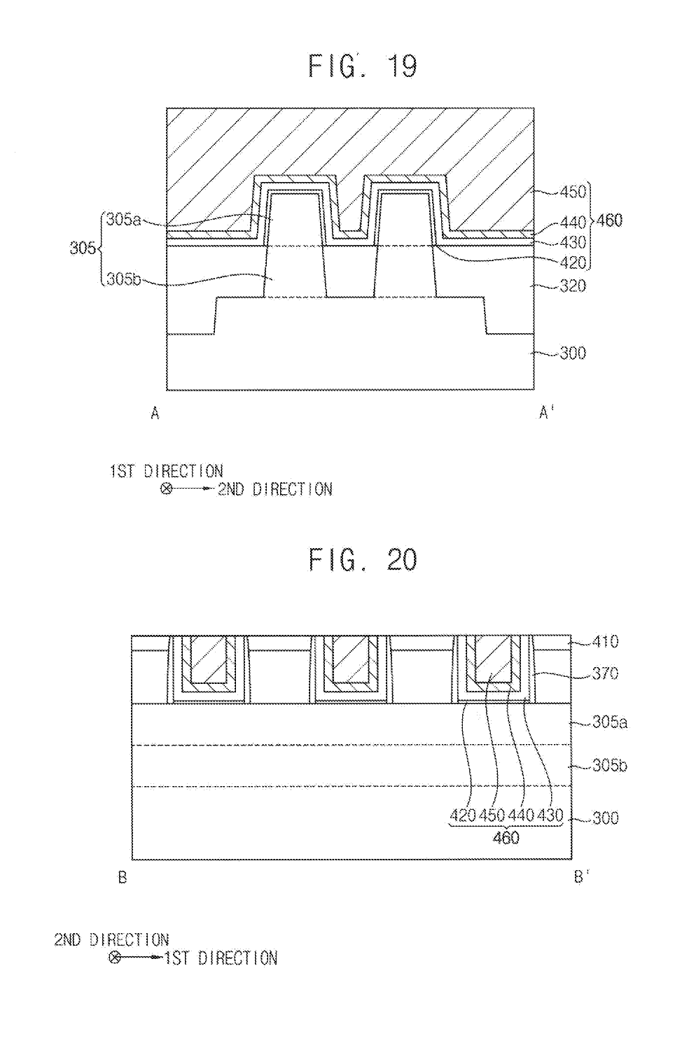

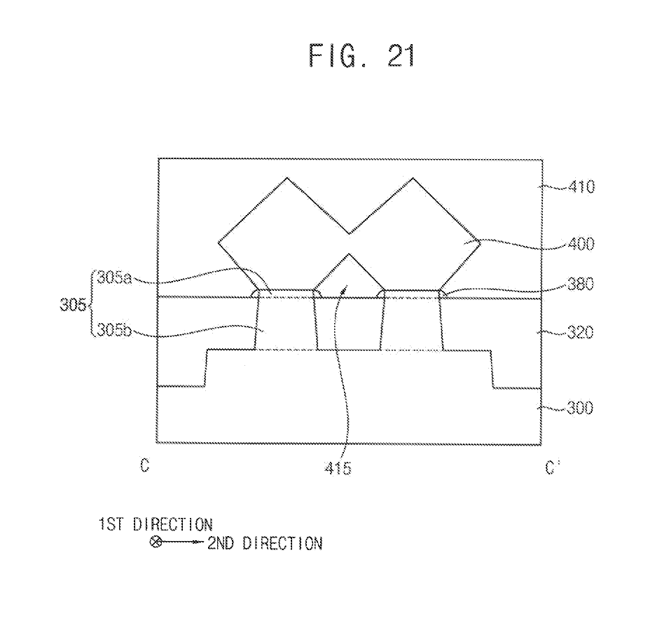

FIGS. 6 to 27 are plan views and cross-sectional views illustrating a method of manufacturing an MRAM device in accordance with example embodiments. Particularly, FIGS. 6, 10, 13 and 18 are plan views, and FIGS. 7-9, 11-12, 14-17 and 19-27 are cross-sectional views.

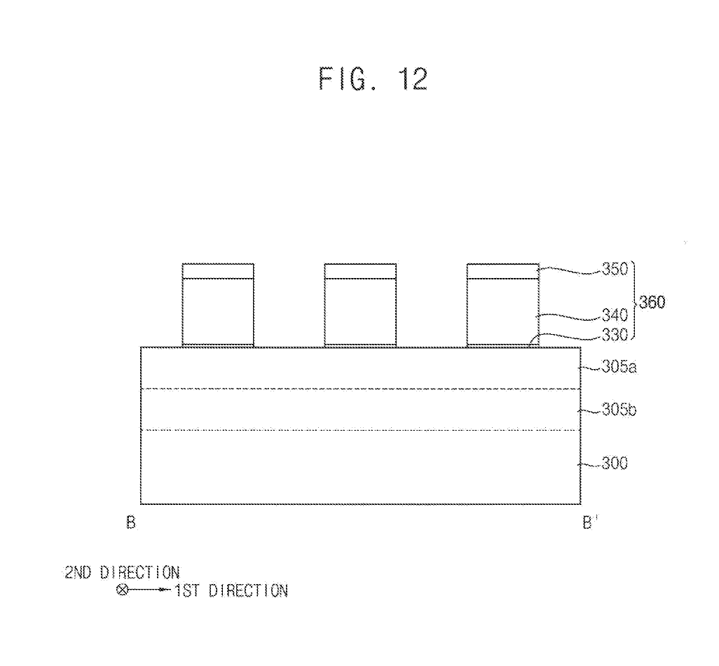

FIGS. 7-9, 11 and 19 are cross-sectional views taken along lines A-A′ of corresponding plan views, FIGS. 12, 14, 16, 20, 22, 24 and 27 are cross-sectional views taken along lines B-B′ of corresponding plan views, and FIGS. 15, 17, 21, 23 and 25-26 are cross-sectional views taken along lines C-C′ of corresponding plan views.

This method of manufacturing the MRAM device may include processes substantially the same as or similar to those illustrated with reference to FIGS. 1 and 2, and detailed descriptions thereof will be omitted herein.

Referring to FIGS. 6 and 7, an upper portion of a substrate 300 may be partially etched to form a first recess 307.

As the first recess 307 is formed on the substrate 300, an active fin 305 and a field region may be defined on the substrate 300. The active fin 305 may be also referred to as an active region.

In example embodiments, the active fin 305 may extend in a first direction. The active fin 305 may be formed in plural. The active fin 305 in plural may be formed in a second direction crossing the first direction. For example, the active fin 305 in plural may be spaced apart from each other in the second direction.

Referring to FIG. 8, a first etching mask 310 may be formed on a portion of the substrate 300, and a portion of the substrate 300 may be removed using the first etching mask 310.

In example embodiments, a portion of the active fin 305 and a portion of the substrate 300 thereunder may be removed, and thus a second recess 315 may be formed on the substrate 300.

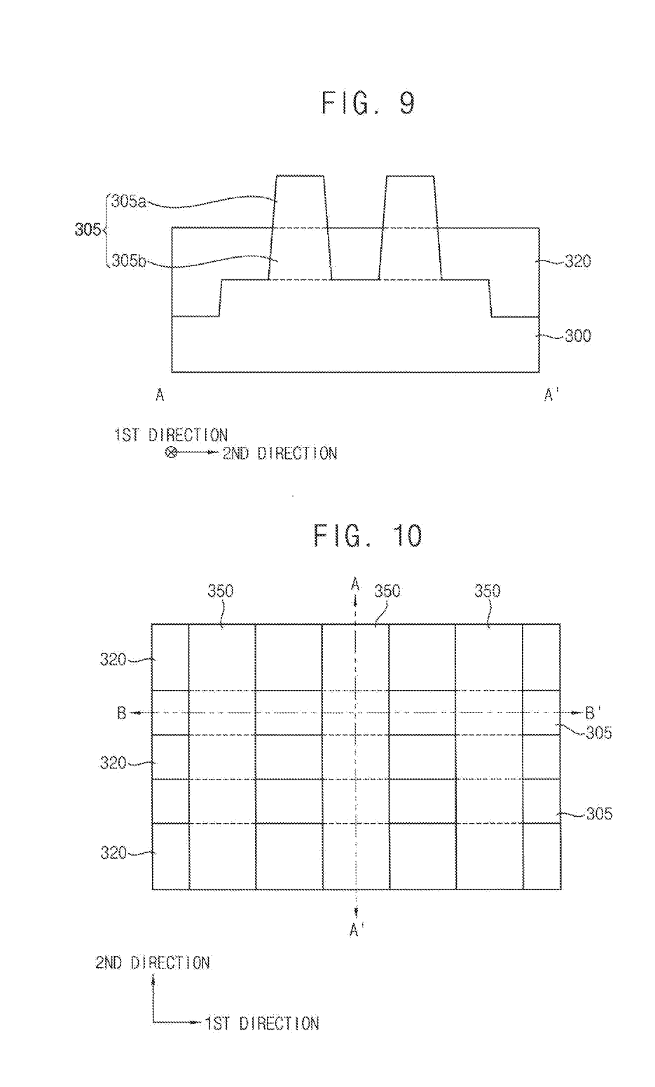

Referring to FIG. 9, after removing the first etching mask 310, an isolation pattern 320 may be formed on the substrate 300 to fill the second recess 315 and a portion of the first recess 307. In an exemplary embodiment, the isolation pattern 320 may fill completely the second recess 315 and partially the first recess 307.

The isolation pattern 320 may be formed by forming an isolation layer on the substrate 300 to fill the first recess 307 and the second recess 315, planarizing the isolation layer until an upper surface of the active fin 305 may be exposed, and an upper portion of the isolation layer may be removed to expose an upper sidewall of the first recess 307.

As the isolation pattern 320 is formed on the substrate 300, the active fin 305 may be divided into a lower active pattern 305b of which a sidewall is covered by the isolation pattern 320, and an upper active pattern 305a protruding from an upper surface of the isolation pattern 320.

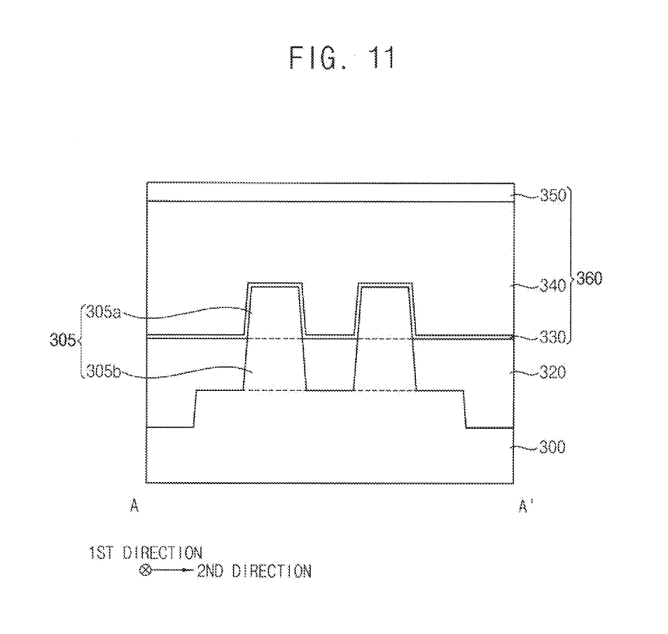

Referring to FIGS. 10 to 12, a dummy gate structure 360 may be formed on the substrate 300.

In an embodiment, the dummy gate structure 360 may be formed by sequentially forming a dummy gate insulation layer, a dummy gate electrode layer, and a dummy gate mask layer on the active fin 305 of the substrate 300 and the isolation pattern 320, patterning the dummy gate mask layer to form a dummy gate mask 350, and etching sequentially the dummy gate electrode layer and the dummy gate insulation layer using the dummy gate mask 350 as an etching mask.

Thus, the dummy gate structure 360 may include a dummy gate insulation pattern 330, a dummy gate electrode 340 and the dummy gate mask 350 sequentially stacked on the substrate 300.

In example embodiments, the dummy gate structure 360 may extend in the second direction. The dummy gate structure 360 may be formed in plural. The dummy gate structure 360 in plural may be formed in the first direction. For example, the dummy gate structure 360 in plural may be spaced apart from each other in the first direction.

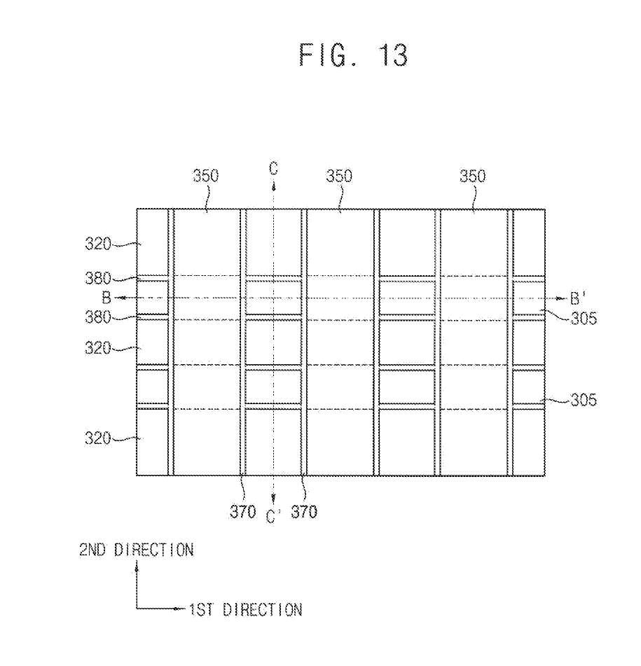

Referring to FIGS. 13 to 15, a gate spacer 370 may be formed on a sidewall of the dummy gate structure 360.

The gate spacer 370 may be formed by forming a spacer layer on the active fin 305 of the substrate 300 and the isolation pattern 320 to cover the dummy gate structure 360, and anisotropically etching the spacer layer. The gate spacer 370 may be formed on the sidewall of the dummy gate structure 360, and a fin spacer 380 may be formed on a sidewall of the upper active pattern 305a.

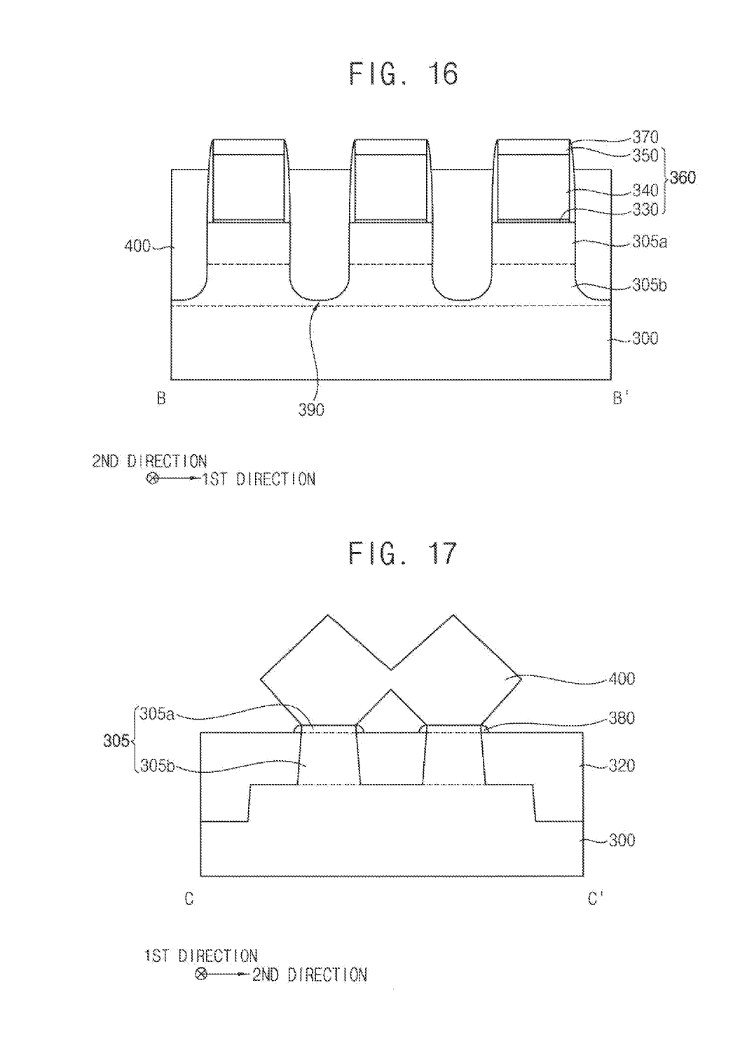

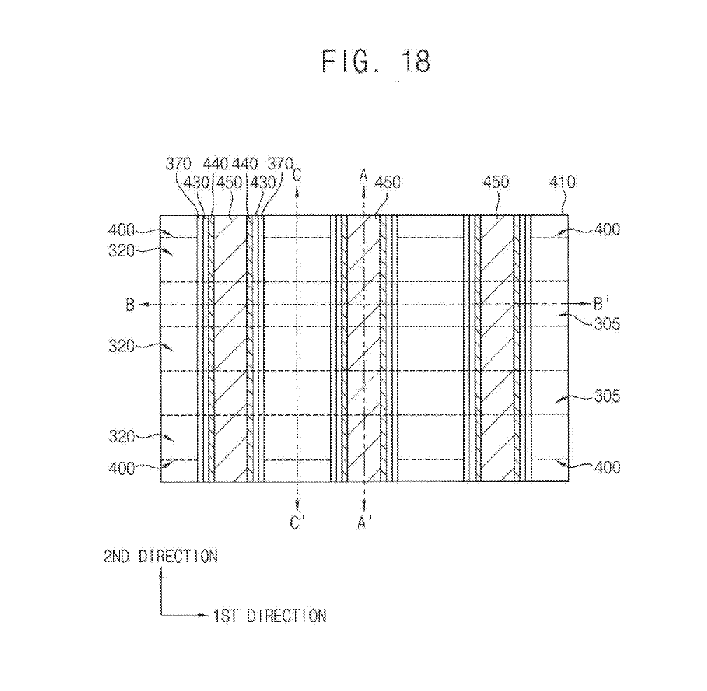

Referring to FIGS. 16 and 17, an upper portion of the active fin 305 adjacent the gate spacer 370 may be etched to form a third recess 390.

In an embodiment, the upper portion of the active fin 305 may be removed by a dry etching process using the dummy gate structure 360 and the gate spacer 370 on the sidewall thereof as an etching mask to form the third recess 390. In the formation of the third recess 390, the fin spacer 380 adjacent to the active fin 305 may be partially removed. For example, an upper portion of the fin spacer 380 may be removed, and a lower portion of the fin spacer 380 may remain on the active fin 305.

A source/drain layer 400 may be formed in the third recess 390.

In example embodiments, the source/drain layer 400 may be formed by a selective epitaxial growth (SEG) process using an upper surface of the active fin 305 exposed by the third recess 390 as a seed.

In example embodiments, by the SEG process, a single crystalline silicon-germanium layer may be formed to serve as the source/drain layer 400. A p-type impurity source gas may be also used in the SEC process to form a single crystalline silicon-germanium layer doped with p-type impurities which serves as the source/drain layer 400. Thus, the source/drain layer 400 may serve as a source/drain region of a PMOS transistor.

The source/drain layer 400 may grow not only in a vertical direction but also in a horizontal direction to fill the third recess 390. The source/drain layer 400 may be in contact with a sidewall of the gate spacer 370.

In example embodiments, when the active fin 305 in plural disposed in the second direction is close to each other, the source/drain layers 400 growing on the active fin 305 in plural may be merged with each other as shown in FIG. 5.

In an embodiment, the source/drain layer 400 serves as the source/drain region of the PMOS transistor. In an embodiment, the source/drain layer 400 serves as a source/drain region of NMOS transistor.

Thus, a single crystalline silicon carbide layer or a single crystalline silicon layer may be formed as the source/drain layer 400. In the SEG process, an n-type impurity source gas may be also used to form a single crystalline silicon carbide layer doped with n-type impurities.

Referring to FIGS. 18 to 21 and FIG. 16, an insulation layer 410 may be formed on the substrate 300 to cover the dummy gate structure 360, the gate spacer 370, the source/drain layer 400, and the fin spacer 380, and then may be planarized until an upper surface of the dummy gate electrode 340 of the dummy gate structure 360 may be exposed.

During the planarization process, the dummy gate mask 350 may be also removed, and an upper portion of the gate spacer 370 may be removed. A space between the merged source/drain layer 400 and the isolation pattern 320 may not be fully filled, and thus an air gap 415 may be formed.

The exposed dummy gate electrode 340 and the dummy gate insulation pattern 330 thereunder may be removed to form a first opening exposing an inner sidewall of the gate spacer 370 and an upper surface of the active fin 305, and a gate structure 460 may be formed to fill the first opening.

The gate structure 460 may be formed by following processes.

A thermal oxidation process may be performed on the exposed upper surface of the active fin 305 by the first opening to form an interface pattern 420. A gate insulation layer and a work function control layer may be sequentially formed on the interface pattern 420, the isolation pattern 320, the gate spacer 370, and the insulation layer 410. A gate electrode layer may be formed on the work function control layer to sufficiently fill a remaining portion of the first opening.

The interface pattern 420 may be formed by a chemical vapor deposition (CVD) process or an atomic layer deposition (ALD) process instead of the thermal oxidation process, and in this case, the interface pattern 420 may be formed not only on the upper surface of the active fin 305 but also on the upper surface of the isolation pattern 320 and the inner wall of the gate spacer 370.

The gate electrode layer, the work function control layer, and the gate insulation layer may be planarized until the upper surface of the insulation layer 410 may be exposed to form a gate insulation pattern 430 and a work function control pattern 440 sequentially stacked on the upper surface of the interface pattern 420, the upper surface of the isolation pattern 320, and the inner wall of the gate spacer 370, and to form a gate electrode 450 filling the remaining portion of the first opening on the work function control pattern 440. Thus, a bottom and a sidewall of the gate electrode 450 may be covered by the work function control pattern 440.

The interface pattern 420, the gate insulation pattern 430, the work function control pattern 440, and the gate electrode 450 sequentially stacked may form the gate structure 460, and the gate structure 460 together with the source/drain layer 400 may form a PMOS transistor or an NMOS transistor according to the conductivity type of the source/drain layer 400.

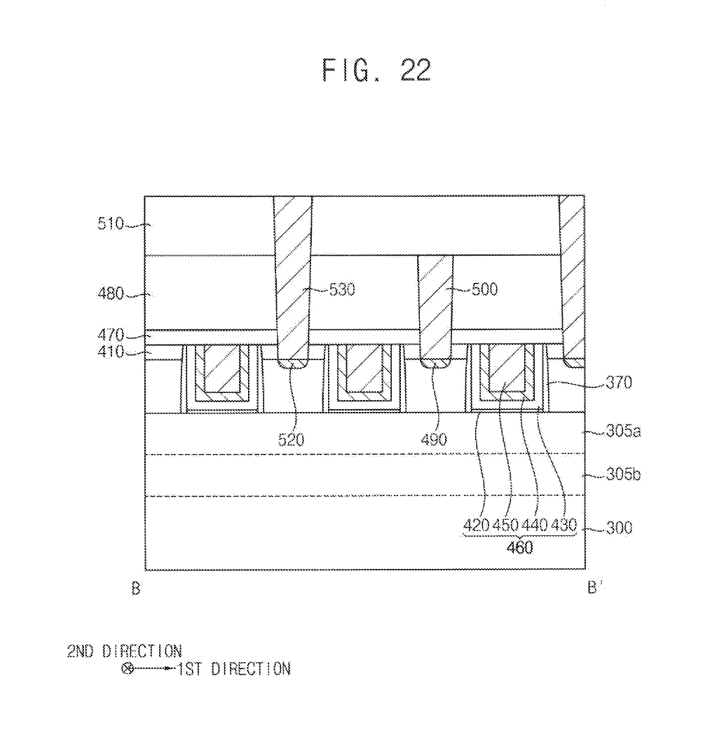

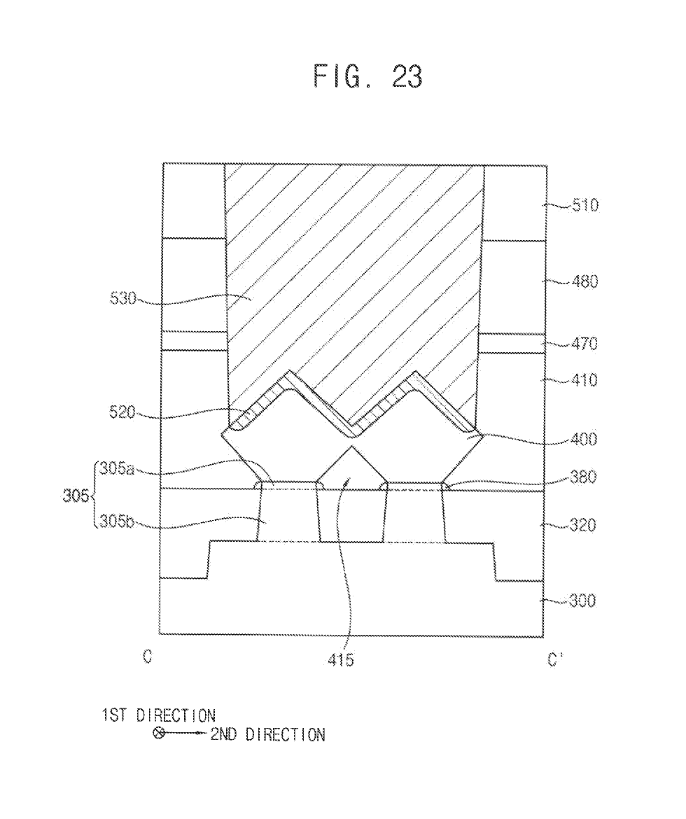

Referring to FIGS. 22 and 23, a capping layer 470 and a first insulating interlayer 480 may be sequentially formed on the insulation layer 410, the gate structure 460, and the gate spacer 370. A source line 500 may be formed through the insulation layer 410, the capping layer 470, and the first insulating interlayer 480 to be in contact with an upper surface of a first source/drain layer of the source/drain layers 400.

The source line 500 may be formed by following processes.

A second opening may be formed through the insulation layer 410, the capping layer 470, and the first insulating interlayer 480 to expose the upper surface of the source/drain layer 400. A first metal layer may be formed on the exposed upper surface of the source/drain layer 400, a sidewall of the second opening, and an upper surface of the first insulating interlayer 480. Thermal treatment may be performed on the first metal layer to form a first metal silicide pattern 490 on the first source/drain layer.

A first barrier layer may be formed on an upper surface of the first metal silicide pattern 490, the sidewall of the second opening, and the upper surface of the first insulating interlayer 480. A first conductive layer may be formed on the first barrier layer to fill the second opening. The first conductive layer and the first barrier layer may be planarized until the upper surface of the first insulating interlayer 480 may be exposed.

Thus, the source line 500 including the first barrier pattern and the first conductive pattern sequentially stacked on the first metal silicide pattern 490 may be formed to fill the second opening.

In example embodiments, the source line 500 may extend in the second direction to a given length. The source line 500 may be formed in plural. The source line 500 may be formed in the first direction. For example, the source lines 500 may be spaced apart from each other in the first direction.

A second insulating interlayer 510 may be formed on the first insulating interlayer 480 and the source line 500. A third opening may be formed through the insulation layer 410, the capping layer 470, the first insulating interlayer 480, and the second insulating interlayer 510 to expose an upper surface of a second source/drain layer of the source/drain layers 400. A second metal layer may be formed on the exposed upper surface of the second source/drain layer, a sidewall of the third opening, and an upper surface of the second insulating interlayer 510. Thermal treatment may be performed on the second metal layer to form a second metal silicide pattern 520 on the second source/drain layer.

A second barrier layer may be formed on an upper surface of the second metal silicide pattern 520, the sidewall of the third opening, and the upper surface of the second insulating interlayer 510. A second conductive layer may be formed on the second barrier layer to fill the third opening. The second conductive layer and the second barrier layer may be planarized until the upper surface of the second insulating interlayer 510 may be exposed.

Thus, a lower contact plug 530 including a second barrier pattern and a second conductive pattern sequentially stacked on the second metal silicide pattern 520 may be formed to fill the third opening.

In example embodiments, the lower contact plug 530 may be formed in plural. The lower contact plug 530 in plural may be formed to be spaced apart from each other in the first direction.

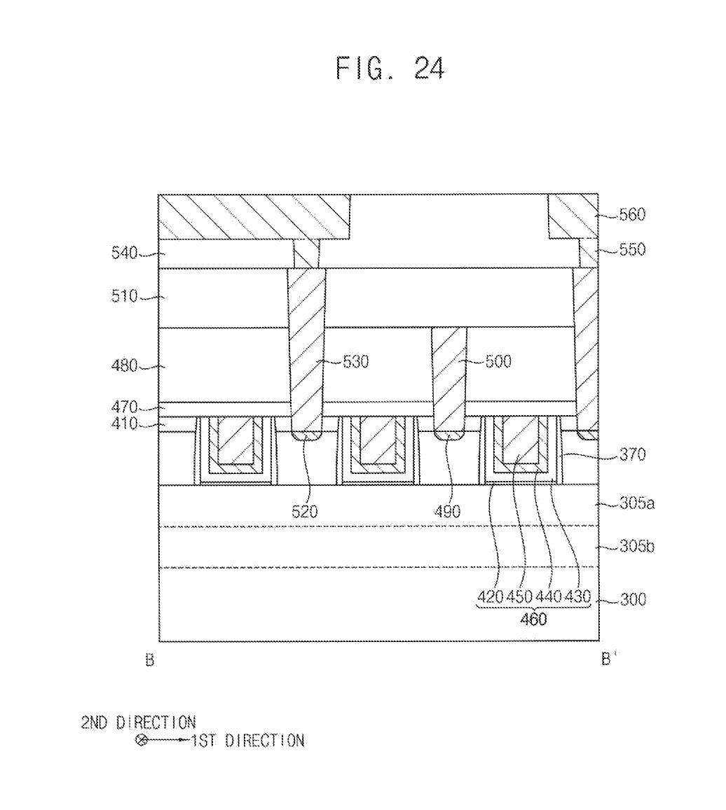

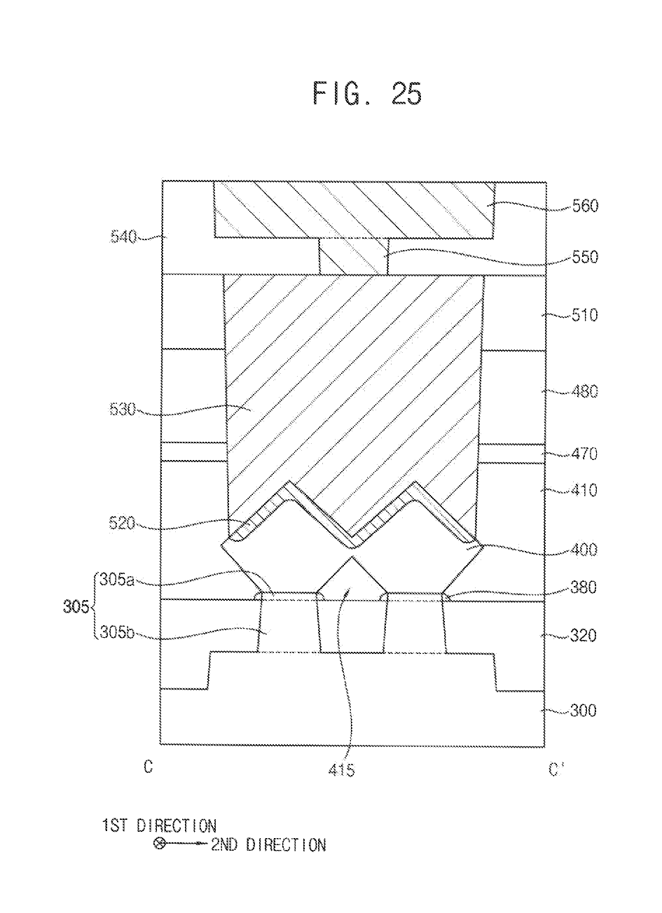

Referring to FIGS. 24 and 25, a third insulating interlayer 540 may be formed on the second insulating interlayer 510 and the lower contact plug 530. A first conductive line 560 extending through an upper portion of the third insulating interlayer 540 and a first via 550 extending through a lower portion of the third insulating interlayer 540 may be formed.

In example embodiments, the first conductive line 560 and the first via 550 may be simultaneously formed by a dual damascene process. Thus, each of the first conductive line 560 and the first via 550 may be formed to include a third conductive pattern and a third barrier pattern covering a bottom and a sidewall of the third conductive pattern.

Alternatively, the first conductive line 560 and the first via 550 may be independently formed by a single damascene process.

In example embodiments, the first conductive line 560 may extend in a second direction. The first conductive line 560 may be formed in plural. The first conductive line 560 in plural may be spaced apart from each other in a first direction. In example embodiments, the first via 550 may be formed beneath the first conductive line 560 to be in contact with an upper surface of the lower contact plug 530.

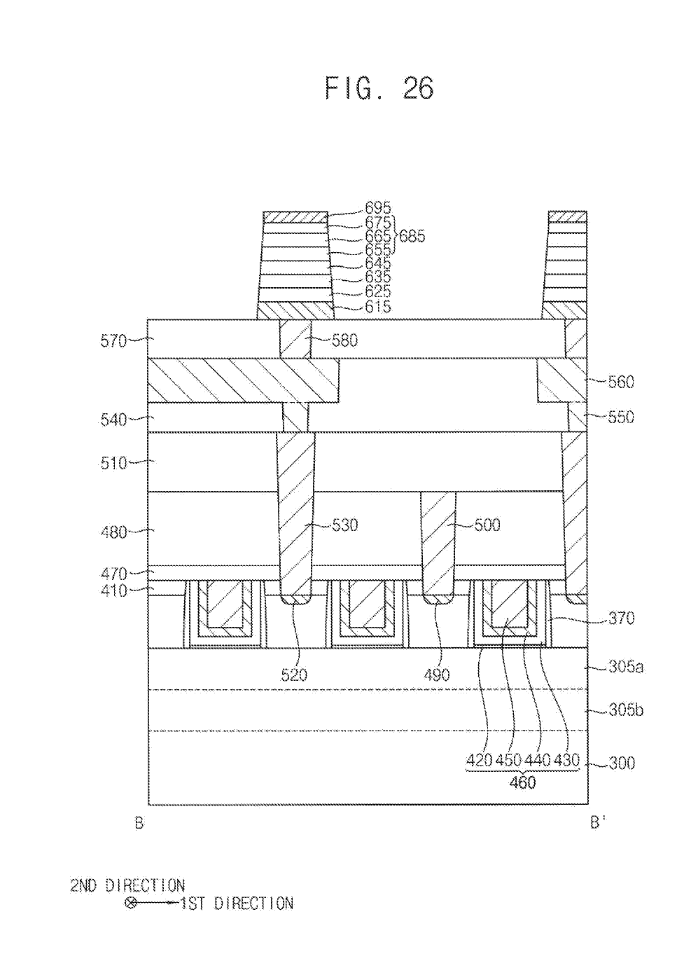

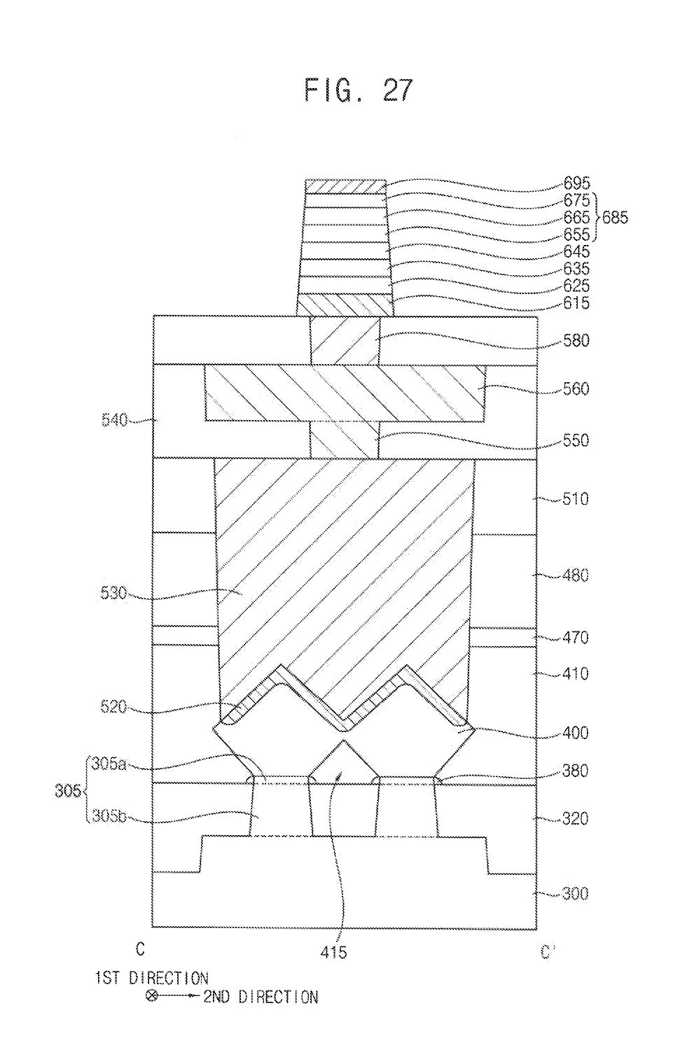

Referring to FIGS. 26 and 27, a fourth insulating interlayer 570 may be formed on the third insulating interlayer 540 and the first conductive line 560. An upper contact plug 580 may be formed through the fourth insulating interlayer 570 to be in contact with the first conductive line 560. For example, the upper contact plug 580 may include a fourth conductive pattern (not shown) and a fourth barrier pattern (not shown) covering a bottom and a sidewall of the fourth conductive pattern.

Processes substantially the same as or similar to those illustrated with reference to FIGS. 1 and 2 may be performed.

That is, a lower electrode 615, a first blocking pattern 625, an adhesion pattern 635, a seed pattern 645, an MTJ structure 685, and an upper electrode 695 may be sequentially formed on the upper contact plug 580. The MTJ structure 685 may include a fixed layer pattern 655, a tunnel barrier layer pattern 665, and a free layer pattern 675 sequentially stacked.

As illustrated above, the first boride formation energy of the first metal of the first blocking pattern 625 may be less than the second boride formation energy of the second metal of the seed pattern 645. In this case, boron of the first blocking pattern 625 including the metal boride may be prevented from diffusing into the seed pattern 645, and the thus the characteristics of the seed pattern 645 may not change by the diffusion of boron from the first blocking pattern 625.

Referring to FIGS. 4 and 5 again, the protection layer 700 may be formed on the fourth insulating interlayer 570 to cover the lower electrode 615, the first blocking pattern 625, the adhesion pattern 635, the seed pattern 645, the MTJ structure 685, and the upper electrode 695, and a fifth insulating interlayer 710 may be formed on the protection layer 700.

A second via 720 and a second conductive line 730 may be formed to extend through an upper portion of the fifth insulating interlayer 710 and in contact with an upper surface of the upper electrode 695. Each of the second via 720 and the second conductive line 730 may include a fifth conductive pattern (not shown) and a fifth barrier pattern (not shown) covering a bottom and a sidewall of the fifth conductive pattern.

In example embodiments, the second conductive line 730 may extend in the second direction to serve as a bit line of the MRAM device.

The first blocking pattern 625 may stay amorphous at a high temperature equal to or more than about 400° C., and thus the first blocking pattern 625 may stay amorphous even in a high temperature process for forming the second via 720 and the second conductive line 730. Accordingly, the influence of the crystallinity of the lower electrode 615 on the crystallinity of the seed pattern 645 may be effectively blocked by the first blocking pattern 625, and the characteristics of the fixed layer pattern 655 on the seed pattern 645 may keep its desired characteristics, e.g., a magnetization direction.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. An MRAM device comprising:
a lower electrode;
a blocking pattern on the lower electrode, the blocking pattern including a binary metal boride in an amorphous state;
a seed pattern on the blocking pattern, the seed pattern including a metal;
an MTJ structure on the seed pattern; and
an upper electrode on the MTJ structure.

2. The MRAM device of claim 1,
wherein the blocking pattern includes one of tantalum boride, titanium boride, hafnium boride, zirconium boride, vanadium boride, niobium boride, and scandium boride.

3. The MRAM device of claim 1,
wherein the blocking pattern includes tantalum boride.

4. The MRAM device of claim 3,
wherein the blocking pattern includes boron in an amount in a range of about 5 wt % to about 40 wt %.

5. The MRAM device of claim 1,
wherein the seed pattern includes one of ruthenium, rhenium, iridium, rhodium, and hafnium.

6. The MRAM device of claim 1,
wherein the seed pattern includes ruthenium.

7. The MRAM device of claim 6,
wherein the blocking pattern includes tantalum boride.

8. The MRAM device of claim 1,
wherein the lower electrode includes titanium nitride, tantalum nitride, or tungsten nitride.

9. The MRAM device of claim 1, further comprising:
an adhesion pattern between the blocking pattern and the seed pattern.

10. The MRAM device of claim 9,
wherein the adhesion pattern includes tantalum.

11. The MRAM device of claim 1,
wherein a first formation energy of the binary metal boride of the blocking pattern is less than a second formation energy for forming a metal boride from a metal of the seed pattern and boron.

12. The MRAM device of claim 1,
wherein a first formation energy of the binary metal boride of the blocking pattern has a negative value.

13. The MRAM device of claim 1,
wherein the binary metal boride of the blocking pattern stays amorphous at a temperature equal to or more than about 400° C.

14. An MRAM device comprising:
a lower electrode;
a blocking pattern on the lower electrode, the blocking pattern including a first metal boride that is formed by combining a first metal and boron;
a seed pattern on the blocking pattern, the seed pattern including a second metal;
an MTJ structure on the seed pattern; and
an upper electrode on the MTJ structure,
wherein a formation energy of the first metal boride is less than a formation energy of a second metal boride that is formed by combining a second metal and boron.

15. The MRAM device of claim 14,
wherein the blocking pattern is in an amorphous state.

16. The MRAM device of claim 14,
wherein the blocking pattern includes only one type of the first metal.

17. The MRAM device of claim 16,
wherein the blocking pattern includes tantalum boride.

18. The MRAM device of claim 14,
wherein the seed pattern includes ruthenium.

19. (canceled)

20. (canceled)

21. An MRAM device comprising:
a lower electrode;
a blocking pattern on the lower electrode, the blocking pattern including a ternary metal boron nitride in an amorphous state;
a seed pattern on the blocking pattern, the seed pattern including a metal;
an MTJ structure on the seed pattern; and
an upper electrode on the MTJ structure.

22. The MRAM device of claim 21,
wherein the blocking pattern includes one of tantalum boron nitride, titanium boron nitride, hafnium boron nitride, zirconium boron nitride, vanadium boron nitride, niobium boron nitride, and scandium boron nitride.

23-33. (canceled)
